(19) United States
(12) Patent Application Publication
(10) Pub. No.: US 2016/0233163 A1
(43) Pub. Date: Aug. 11, 2016

(54) SEMICONDUCTOR DEVICE AND METHOD OF MANUFACTURING SEMICONDUCTOR DEVICE

(71) Applicant: Kabushiki Kaisha Toshiba, Minato-ku (JP)

(72) Inventors: Shoichi WATANABE, Yokkaichi (JP); Kiyoshi OKUYAMA, Yokkaichi (JP); Kimitoshi OKANO, Yokkaichi (JP)

(73) Assignee: Kabushiki Kaisha Toshiba, Minato-ku (JP)

(21) Appl. No.: 14/731,525

(22) Filed: Jun. 5, 2015

Related U.S. Application Data
(60) Provisional application No. 62/114,415, filed on Feb. 10, 2015.

(51) Int. Cl. H01L 23/535; H01L 23/528; H01L 21/8234; H01L 27/088; H01L 29/423

(52) U.S. Cl. CPC H01L 23/535; H01L 27/088; H01L 29/42364; H01L 21/823475; H01L 23/528

(57) ABSTRACT

A semiconductor device according to an embodiment includes a first transistor and a second transistor. The first transistor is connected to a first wiring through a wiring plug made of a material having a first resistance value smaller than a predetermined value. In addition, at least any one of a drain and a source of the second transistor is connected to a second wiring through a polysilicon plug made of a material having a second resistance value larger than the first resistance value.

### CROSS-REFERENCE TO RELATED APPLICATIONS

This application is based upon and claims the benefit of priority from U.S. Provisional Application No. 62/114,415, filed on Feb. 10, 2015; the entire contents of which are incorporated herein by reference.

### FIELD

Embodiments described herein relates generally to a semiconductor device and a method of manufacturing the semiconductor device.

### BACKGROUND

Among MOS (Metal Oxide Semiconductor) transistors as an example of a semiconductor device, there is a high breakdown voltage transistor for which a high breakdown voltage is required in a drain or the like. Such a high breakdown voltage transistor is configured to have a wide element area in order to increase the breakdown voltage of the drain.

However, when the element area is widened, the semiconductor device is increased in area. Therefore, it is desirable that the high breakdown voltage transistor be formed while suppressing the increase of a circuit area.

### BRIEF DESCRIPTION OF THE DRAWINGS

FIG. 1 is a diagram illustrating an exemplary configuration of a transistor according to a first embodiment;

FIG. 2 is a diagram for describing a resistance value in a drain of the transistor according to the first embodiment;

FIG. 3 is a diagram for describing the resistance value in the drain in a case where a plug portion connected to the drain is made of metal;

FIG. 4 is a diagram for describing a breakdown voltage of the drain in a case where the resistance of a wiring plug is low;

FIG. 5 is a diagram illustrating a relation between a sheet resistance of an n-type diffusion layer and a breakdown voltage of the drain;

FIG. 6 is a diagram illustrating an exemplary configuration of a transistor which is manufactured to have a long distance between a gate and a second n⁺ layer;

FIG. 7 is a flowchart illustrating a procedure of forming the transistor according to the first embodiment;

FIG. 8 is a diagram illustrating an exemplary configuration of a transistor according to a second embodiment; and

FIG. 9 is a diagram illustrating an exemplary configuration of a transistor according to a third embodiment.

### DETAILED DESCRIPTION

According to the embodiments, there is provided a semiconductor device. The semiconductor device includes a first transistor and a second transistor. The first transistor is connected to a first wiring through a wiring plug made of a material having a first resistance value smaller than a predetermined value. In addition, at least one of a drain and a source of the second transistor is connected to a second wiring through a polysilicon plug made of a material having a second resistance value larger than the first resistance value.

A semiconductor device and a method of manufacturing the semiconductor device according to embodiments will be described in detail with reference to the accompanying drawings below. Further, the invention is not limited to these embodiments.

### First Embodiment

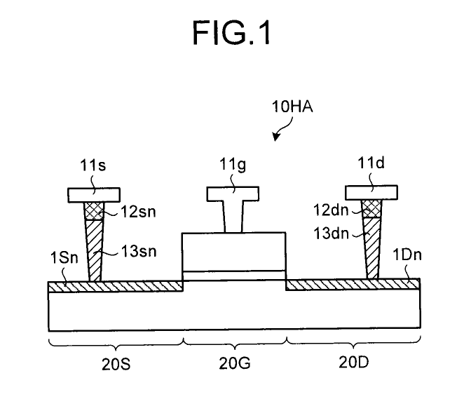

FIG. 1 is a diagram illustrating an exemplary configuration of a transistor according to a first embodiment. FIG. 1 illustrates a cross-sectional configuration of a MOS (Metal Oxide Semiconductor) transistor (a transistor 10HA). The transistor 10HA is a transistor (a semiconductor device) which is required for a high breakdown voltage. Further, the transistor 10HA may be an nMOS transistor, or may be a pMOS transistor. In the following, the description will be made about a case where the transistor 10HA is the nMOS transistor (an HV nMOS).

In a transistor circuit of the embodiment, a low breakdown voltage transistor is connected to a first wiring through a wiring plug (a contact plug) made of a material having a first resistance value smaller than a predetermined value. Then, the transistor 10HA having a high breakdown voltage is connected to a second wiring through a polysilicon plug (a polysilicon layer) made of a material having a second resistance value larger than the first resistance value. With this configuration, the breakdown voltage of the drain of the transistor 10HA is improved using a small area.

The transistor 10HA includes a source 20S, a gate 20G, and a drain 20D. Then, the source 20S, the gate 20G, and the drain 20D are connected to a contact plug or a wiring layer (an interconnect layer) on an upper layer side of the transistor 10HA. The source 20S includes an n-type diffusion layer 1Sn, and the drain 20D includes an n-type diffusion layer 1Dn. In the transistor 10HA, the gate 200 is formed between the source 20S and the drain 20D.

The n-type diffusion layers 1Sn and 1Dn is formed by a first n⁻ layer (a silicon layer) having an impurity concentration lower than a predetermined value. The n-type diffusion layers 1Sn and 1Dn, for example, are simultaneously formed in the same process to have the same impurity concentration. Further, the impurity concentration of the n-type diffusion layer 1Sn and the impurity concentration of the n-type diffusion layer 1Dn may be different from each other.

The contact plug (the polysilicon plug) connected to a wiring layer 11s is provided on the upper layer side of the n-type diffusion layer 1Sn. Therefore, the source 20S and the wiring layer 11s are connected through the contact plug. The wiring layer 11s, for example, is a metal wiring layer.

The contact plug connected to the source 20S includes a plug portion 12sn and a plug portion 13sn. The plug portion 12sn is formed on the upper portion side of the plug portion 13sn. Therefore, the plug portion 13sn is formed on the upper layer side of the n-type diffusion layer 1Sn, and the plug portion 12sn is formed in the upper portion of the plug portion 13sn.

The plug portion 12sn is formed by a first n⁺ layer (the polysilicon layer) having an impurity concentration higher than a predetermined value, and the plug portion 13sn is formed by a second n layer (the polysilicon layer) having an impurity concentration lower than a predetermined value. The first n⁺ layer may have an impurity concentration at which the wiring layer 11s and the plug portion 12sn come into ohmic contact with each other. Therefore, in a case where the wiring layer 11s is a polysilicon, the plug portion 12sn may be formed by the first or second n⁻ layer. In addition, in a case where the breakdown voltage required for the source 20S is lower than a predetermined value, the plug portions 12sn and 13sn may be formed using a metal layer.

The contact plug (the polysilicon plug) connected to a wiring layer lid is provided on the upper layer side of the n-type diffusion layer 1Dn. Therefore, the drain 20D and the wiring layer lid are connected through the contact plug. The wiring layer 11d, for example, a metal wiring layer.

The contact plug connected to the drain 20D includes a plug portion 12dn and a plug portion 13dn. The plug portion 12dn is formed on the upper portion side of the plug portion 13dn. Therefore, the plug portion 13dn is formed on the upper layer side of the n-type diffusion layer 1Dn, and the plug portion 12dn is formed on the upper portion side of the plug portion 13dn.

The plug portion 12dn is formed by the first n⁺ layer (the polysilicon layer) having an impurity concentration higher than a predetermined value. In other words, the plug portion 12dn is formed using a material having a resistance value lower than a predetermined value.

In addition, the plug portion 13dn is formed by the second n⁻ layer (the polysilicon layer) having an impurity concentration lower than a predetermined value. In other words, the plug portion 13dn is formed using a material having a resistance value higher than a predetermined value.

The first n⁺ layer may have an impurity concentration at which the wiring layer lid and the plug portion 12dn come into ohmic contact with each other. Therefore, in a case where the wiring layer lid is polysilicon, the plug portion 12dn may be formed by the first or second n⁻ layer.

Further, the impurity concentration of the plug portion 12dn and the impurity concentration of the plug portion 12sn may be different from each other. In addition, the impurity concentration of the plug portion 13dn and the impurity concentration of the plug portion 13sn may be different from each other. The plug portions 12dn and 12sn are simultaneously formed in the same process to have the same impurity concentration. In addition, the plug portions 13dn and 13sn are simultaneously formed in the same process to have the same impurity concentration.

The gate 20G is connected to a wiring layer (a wiring plug) 11g. The wiring layers 11s, 11d, and 11g are formed using a material having a resistance value lower than a predetermined value. The wiring layers 11s, 11d, and 11g, for example, are metal wiring layers. Further, the wiring layers 11s, 11d, and 11g may be made of polysilicon having an even impurity concentration.

In the transistor 10HA, the gate 20G is connected to the first wiring layer through the wiring layer 11g. In addition, in the transistor 10HA, the drain 20D (the n-type diffusion layer 1Dn) is connected to the second wiring layer through the wiring layer 11d.

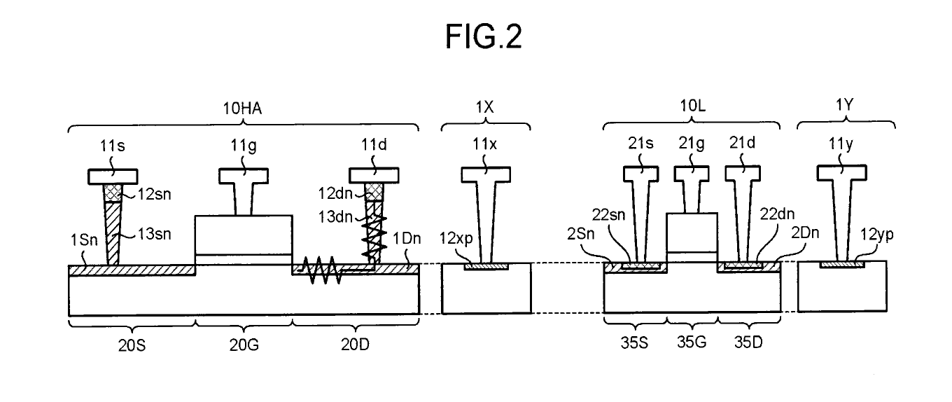

Next, the resistance value of the drain 20D of the transistor 10HA will be described. FIG. 2 is a diagram for describing the resistance value of the drain of the transistor according to the first embodiment. FIG. 2 illustrates a cross-sectional configuration of the transistor circuit which includes the transistor 10HA.

The transistor circuit includes the transistors 10HA and 10L. The transistor 10L is an nMOS transistor having a low breakdown voltage (LV nMOS) compared to the transistor 10HA. The thickness of a gate oxide film of the transistor 10HA is thicker than that of the transistor 10L.

The transistor 10L includes a source 35S, a gate 35G, a drain 35D, and a substrate connecting portion 1Y. The source 35S includes an n-type diffusion layer 2Sn, and the drain 35D includes an n-type diffusion layer 2Dn. In the transistor 10L, the gate 35G is formed between the source 35S and the drain 35D. The n-type diffusion layers 2Sn and 2Dn is formed by the first n⁻ layer similarly to the n-type diffusion layers 1Sn and 1Dn.

An n-type diffusion layer 22sn having an impurity concentration higher than a predetermined value is formed on the upper layer side of the n-type diffusion layer 2Sn. The n-type diffusion layer 22sn is formed by a second n⁺ layer (the polysilicon layer) having an impurity concentration higher than a predetermined value. The second n⁺ layer is a layer having an impurity concentration higher than that of the first n⁻ layer. A wiring plug 21s is provided on the upper layer side of the n-type diffusion layer 22sn.

An n-type diffusion layer 22dn having an impurity concentration higher than a predetermined value is formed on the upper layer side of the n-type diffusion layer 2Dn. The n-type diffusion layer 22dn is formed by the second n⁺ layer. A wiring plug 21d is provided on the upper layer side of the n-type diffusion layer 22dn.

The gate 35G is connected to a wiring layer 21g. The wiring layer 21g is a metal wiring layer similarly to the wiring layer 11g. The wiring plugs 21s and 21d and the wiring layer 21g, for example, are formed simultaneously with the wiring layers 11s, 11d, and 11g in the same process as that of the wiring layers 11s, 11d, and 11g. Further, the wiring plugs 21s and 21d and the wiring layer 21g may be made of polysilicon having an even impurity concentration.

A substrate connecting portion (a well connecting portion in a case where a well is configured) 1X includes a p-type diffusion layer 12xp and a wiring plug 11x. The substrate connecting portion 1X is connected to the substrate (or the well) through the p-type diffusion layer 12xp. In addition, the substrate connecting portion (a well connecting portion in a case where a well is configured) 1Y includes a p-type diffusion layer 12yp and a wiring plug 11y. The substrate connecting portion 1Y is connected to the substrate (or the well) through the p-type diffusion layer 12yp. The p-type diffusion layers 12xp and 12yp are formed a first p⁺ layer (a silicon layer) having an impurity concentration higher than a predetermined value.

The wiring plug 11x is provided on the upper layer side of the p-type diffusion layer 12xp. The wiring plug 11y is provided on the upper layer side of the p-type diffusion layer 12yp. The wiring plugs 11x and fly, for example, are formed simultaneously with the wiring layers 11s, 11d, and 11g in the same process as that of the wiring layers 11s, 11d, and 11g.

Resistance caused by the n-type diffusion layer 1Dn and resistance caused by the plug portions 12dn and 13dn are generated between the wiring layer 11d and the gate 20G of the transistor 10HA. Therefore, in the transistor 10HA, since having the plug portion 13dn a large resistance value is connected to the drain 20D, a large resistance value appears in the drain 20D. With this configuration, the breakdown voltage of the drain 20D is improved.

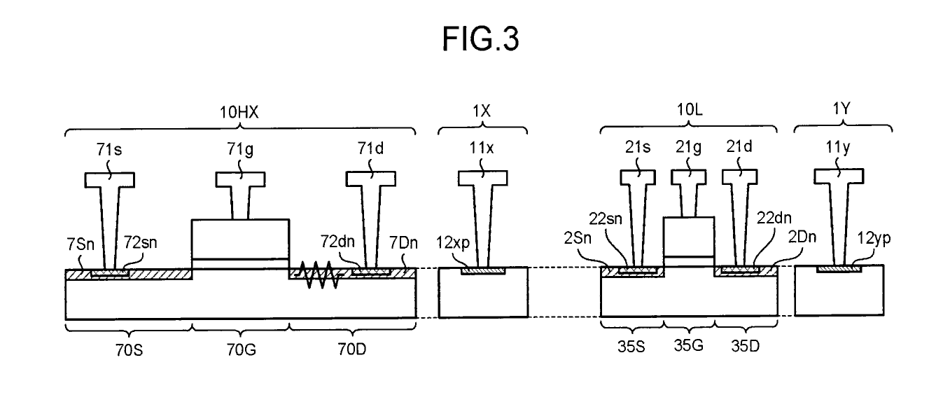

FIG. 3 is a diagram for describing the resistance value of the drain in a case where the plug portion connected to the drain is made of metal. FIG. 3 illustrates the cross-sectional configuration of the transistor circuit. In the transistor circuit illustrated in FIG. 3, the transistor 10L (including the ground connecting portion 1Y) and the ground connecting portion 1X of a transistor 10HX have the same configuration as that of the CMOS transistor illustrated in FIG. 2. The transistor circuit herein includes the transistors 10HX and 10L.

The transistor 10HX includes a source 70S, a gate 70G, a drain 70D, and the substrate connecting portion 1X. The source 70S includes an n-type diffusion layer 7Sn, and the drain 70D includes an n-type diffusion layer 7Dn. In the transistor 10HX, the gate 70G is formed between the source 70S and the drain 70D. The n-type diffusion layers 7Sn and 7Dn, for example, are formed by the first n⁻ layer similarly to the n-type diffusion layers 2Sn and 2Dn.

An n-type diffusion layer 72sn having an impurity concentration higher than a predetermined value is formed on the upper layer side of the n-type diffusion layer 7Sn. The n-type diffusion layer 72sn is formed by the second n⁺ layer (a silicon layer) similarly to the n-type diffusion layer 22sn. A wiring plug 71s is provided on the upper layer side of the n-type diffusion layer 72sn.

An n-type diffusion layer 72dn having an impurity concentration higher than a predetermined value is formed on the upper layer side of the n-type diffusion layer 7Dn. The n-type diffusion layer 72dn is formed by the second n⁺ layer similarly to the n-type diffusion layer 72sn. A wiring plug 71d is provided on the upper layer side of the n-type diffusion layer 72dn.

The gate 70G is connected to a wiring layer 71g. The wiring layer 71g is a metal wiring layer similarly to the wiring layer 11g. The wiring plugs 71s and 71d and the wiring layer 71g, for example, are formed simultaneously with the wiring plugs 21s and 21d and the wiring layer 21g in the same process as that of the wiring plugs 21s and 21d and the wiring layer 21g. Further, the wiring plugs 71s and 71d and the wiring layer 71g may be made of polysilicon having an even impurity concentration.

The transistor 10HX is configured to have the wiring plug 71d of a low resistance, so that the breakdown voltage of the drain 70D becomes lower. In other words, the breakdown voltage of the drain 70D becomes lower than that of the drain 20D.

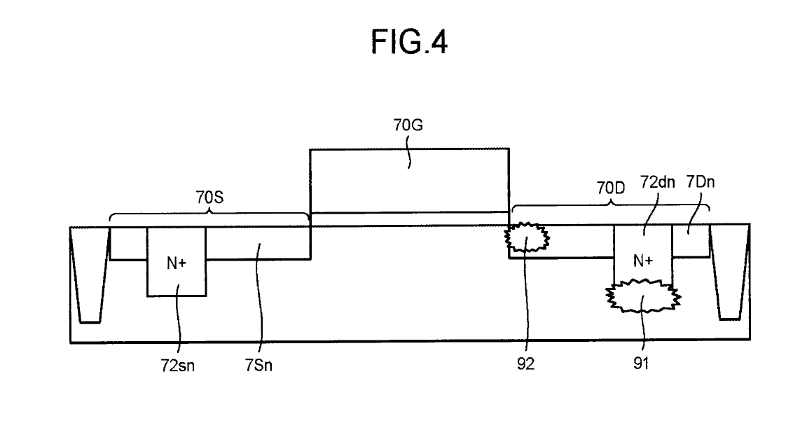

FIG. 4 is a diagram for describing the breakdown voltage of the drain in a case where the resistance of the wiring plug is low. The breakdown voltage of the drain 70D depends on a sheet resistance (a region except the n-type diffusion layer 72dn) of the n-type diffusion layer 7Dn. For example, in a case where the impurity concentration of the n-type diffusion layer 7Dn is lower than a predetermined value, the breakdown voltage depends on an electric field focusing on a boundary surface (bottom) 91 of the n-type diffusion layer 72dn. Therefore, in a case where the impurity concentration of the n-type diffusion layer 7Dn is lower than the predetermined value, the breakdown voltage of the drain 70D depends on the impurity concentration of the n-type diffusion layer 72dn. The breakdown voltage of the drain 70D in this case is improved by alleviating the electric field under the n-type diffusion layer 72dn.

On the other hand, in a case where the impurity concentration of the n-type diffusion layer 7Dn is higher than the predetermined value, the electric field is focused on the boundary surface (the end of the gate) 92 between the n-type diffusion layer 7Dn and the gate 70G. Therefore, in a case where the impurity concentration of the n-type diffusion layer 7Dn is higher than the predetermined value, the breakdown voltage of the drain 70D depends on the impurity concentration of the n-type diffusion layer 7Dn. The breakdown voltage of the drain 70D in this case is improved by alleviating the electric field between the gate 70G and the n-type diffusion layer 7Dn.

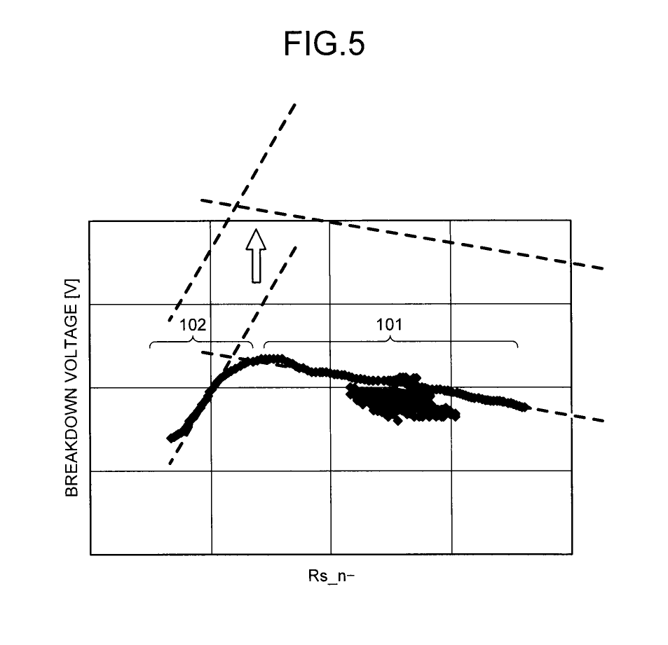

FIG. 5 is a diagram illustrating a relation between a sheet resistance of the n-type diffusion layer and the breakdown voltage of the drain. The horizontal axis of FIG. 5 represents the sheet resistance of the n-type diffusion layer 7Dn (the first n⁻ layer), and the vertical axis represents the breakdown voltage of the drain 70D.

In a case where the impurity concentration of the n-type diffusion layer 7Dn is lower than the predetermined value, the sheet resistance of the n-type diffusion layer 7Dn and the breakdown voltage of the drain 70D show a relation denoted by the characteristic 101. In addition, in a case where the impurity concentration of the n-type diffusion layer 7Dn is higher than the predetermined value, the sheet resistance of the n-type diffusion layer 7Dn and the breakdown voltage of the drain 70D show a relation denoted by the characteristic 102. Therefore, in general, “n-Rs” is set such that the breakdown voltage is maximized in the boundary between the characteristic 102 and the characteristic 101.

As one of the methods of improving the breakdown voltage of the drain 70D, there is a method of lengthening a length between the gate 70G and the n-type diffusion layer 72dn (the wiring plug 71d). In this method, the length of the n-type diffusion layer 7Dn disposed from the distance of the gate 70G to the n-type diffusion layer 72dn becomes lengthy. As a result, the area of the n-type diffusion layer 7Dn becomes larger.

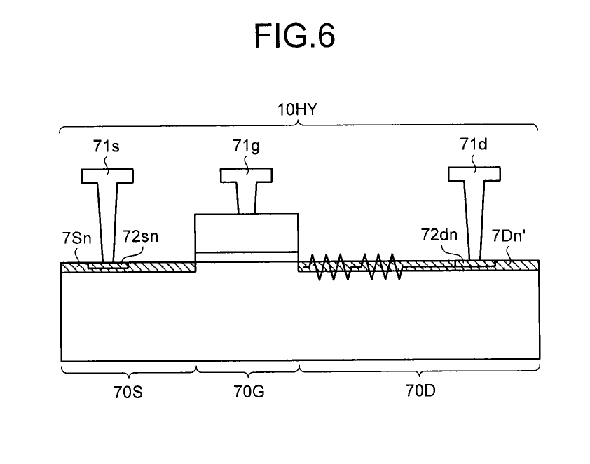

FIG. 6 is a diagram illustrating an exemplary configuration of a transistor of which the length between the gate and the second n⁺ layer is set to be lengthy. FIG. 6 illustrates a cross-sectional configuration of a transistor 10HY in a case where the length between the gate 70G and the n-type diffusion layer 72dn is set to be lengthy.

In a case where the length between the gate 70G and the n-type diffusion layer 72dn is set to be lengthy, an n-type diffusion layer 7Dn′ is used instead of the n-type diffusion layer 7Dn. The n-type diffusion layer 7Dn′ is a diffusion layer which is formed to have a length between the gate 70G and the n-type diffusion layer 72dn longer than that of the n-type diffusion layer 7Dn. With this configuration, it is possible to make the resistance large between the n-type diffusion layer 72dn and the gate 70G, and the breakdown voltage of the area of the characteristic 102 of FIG. 5 can be increased. Therefore, it is possible to increase a maximum breakdown voltage determined at an intersection between the characteristic 102 and the characteristic 101.

However, in the case of the transistor 10HY illustrated in FIG. 6, the area of the transistor 10HY becomes larger. Herein, in this embodiment, as illustrated in FIG. 1, the plug portion 12sn of the drain 20D is formed by the first n⁺ layer, and the plug portion 13sn is formed by the second n layer. With this configuration, the transistor 10HA can be formed in a small area and make the resistance large in a portion between the plug portion 12dn and the gate 20G, and the breakdown voltage of the characteristic 102 can be increased. In addition, since the plug portion 12dn of a high impurity layer is separated from a pn junction place between the diffusion layer and the substrate, the electric field of the pn junction is weakened and the breakdown voltage of the characteristic 101 is also improved. With both effects described above, a maximum breakdown voltage of the drain 20D becomes larger than that of the transistor 10HY.

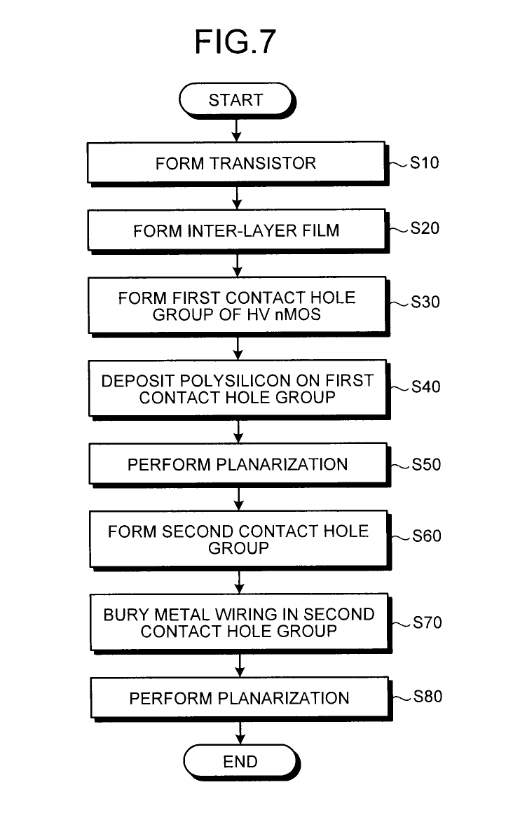

In other words, a procedure of forming a transistor device having the transistor 10HA will be described. FIG. 7 is a flowchart illustrating a procedure of forming the transistor according to the first embodiment. In this embodiment, a first contact hole group is formed in the transistor, and then a second contact hole group is formed.

Among the contact holes connected to the transistor, the contact holes of the source 20S and the drain 20D of the transistor 10HA are the first contact hole group. In addition, among the contact holes connected to the transistor, the contact holes other than the first contact hole group are the second contact hole group. Therefore, the second contact hole group are the contact holes of the gate 20G, the transistor 10L, and the substrate connecting portions 1X and 1Y of the transistor 10HA.

On the substrate of the well, the gate (the gate 20G), a drain diffusion layer, a source diffusion layer, a diffusion layer for the connection of the substrate of the transistor (the transistors 10HA and 10L) are formed (Step S10).

Thereafter, an inter-layer film is formed on the layers (Step S20). Thereafter, the first contact hole group is formed on the upper portion side of the source diffusion layer 20S and the drain diffusion layer 20D of the transistor 10HA (an HV nMOS). At this time, a lithography process or an imprint process is performed, and thus the first contact hole group using a resist pattern is formed. Then, RIE (Reactive Ion Etching) or the like is performed on the resist pattern to form the first contact hole group in the inter-layer film (Step S30).

Furthermore, polysilicon is deposited in the first contact hole group (Step S40). The polysilicon contains n-type impurities such as As and P. Therefore, the plug portions 12sn, 12sn, 12dn, and 13dn are formed on the transistor 10HA. Thereafter, planarization is performed (Step S50).

Furthermore, other contact holes (the second contact hole group) except the HV nMOS are formed. At this time, the lithography process or the imprint process is performed, and thus the second contact hole group using the resist pattern is formed. Then, the RIE is formed on the resist pattern, so that the second contact hole group is formed in the inter-layer film (Step S60). Furthermore, metal wirings are buried in the second contact hole group (Step S70). Therefore, the wiring layers 11g and 21g and the wiring plugs 21s, 21d, 11x, and 11y are formed. Thereafter, the planarization is performed (Step S80).

Further, regarding the contact holes connected to the CMOS transistor, the second contact hole group is first formed and then the first contact hole group may be formed. In this case, after the second contact hole group is formed, the metal wiring is buried in the second contact hole group. Thereafter, the first contact hole group is formed, and the polysilicon is deposited in the first contact hole group.

In addition, the plug portions 12sn and 12sn of the source 20S may be included in the second contact hole group. In this case, the first contact hole group becomes the plug portions 12dn and 13dn.

When the semiconductor device (a semiconductor integrated circuit) is manufactured, the transistor device having the transistor 10HA, the plug portions 12sn, 12sn, 12dn, and 13dn, the wiring layers 11g and 21g, and the wiring plugs 21s, 21d, 11x, and 11y are formed through the procedure described in FIG. 7.

Thereafter, a film forming process, an exposure process, a develop process, and an etching process are performed on each layer of a wafer process. Specifically, the substrate deposited with the resist pattern is exposed to light using a mask, and then the substrate is developed to form the resist pattern on the substrate. Then, the lower layer of the resist pattern is etched using the resist pattern as the mask. Therefore, an actual pattern corresponding to the resist pattern is formed on the substrate. When the semiconductor device is manufactured, the film forming process, the exposure process, the develop process, and the etching process described above are repeatedly performed on each layer.

Next, the impurity concentration such as the plug portions 12sn and 12sn will be described. The impurity concentration of the plug portions 12sn and 13dn, for example, is less than 1×10¹⁹/cm³. In addition, the impurity concentration of the n-type diffusion layers 1Sn and 1Dn, for example, is less than 1×10¹⁹/cm³. In addition, the impurity concentration of the plug portions 12sn and 12dn, for example, is equal to or more than 1×10¹⁹/cm³. In other words, the impurity concentrations of the first n⁻ layer and the second n⁻ layer, for example, are less than 1×10¹⁹/cm³. In addition, the impurity concentration of the first n⁺ layer, for example, is equal to or more than 1×10¹⁹/cm³. Further, the boundary of the impurity concentration of the first and second n layers and the impurity concentration of the first n⁺ layer may be arbitrarily set within a range of 1×10¹⁷ to 1×10²¹/cm³.

Further, in a case where the transistor 10HA is a pMOS transistor, the plug formed on the upper portion side of the source or the drain is formed by a polysilicon layer having a resistance value higher than a predetermined value. The polysilicon contains p-type impurities such as B. In this case, the impurity concentration of the lower layer of the plug formed on the upper portion side of the source or the drain, for example, is less than a first value. For example, the impurity concentration of the lower layer of the plug formed on the upper portion side of the source is equal to the impurity concentration of the p-type diffusion layer which forms the source. In addition, the impurity concentration of the upper portion side of the plug on the upper portion side of the source, for example, equal to or more than the first value.

In this way, according to the first embodiment, the transistor circuit includes the transistor 10HA and the transistor 10L. Then, the transistor 10L is connected to the first wiring through the wiring plug made of a material having the first resistance value smaller than a predetermined value. In addition, the drain 20D of the transistor 10HA is connected to the second wiring through the polysilicon plug made of a material having the second resistance value larger than the first resistance value.

With this configuration, in the drain 20D, the resistance in a portion between the high impurity layer and the gate 20G can be made large and the electric field of the pn junction between the diffusion layer and the substrate can be weakened. As a result, a high breakdown voltage transistor can be effectively formed while suppressing the increase of the circuit area.

### Second Embodiment

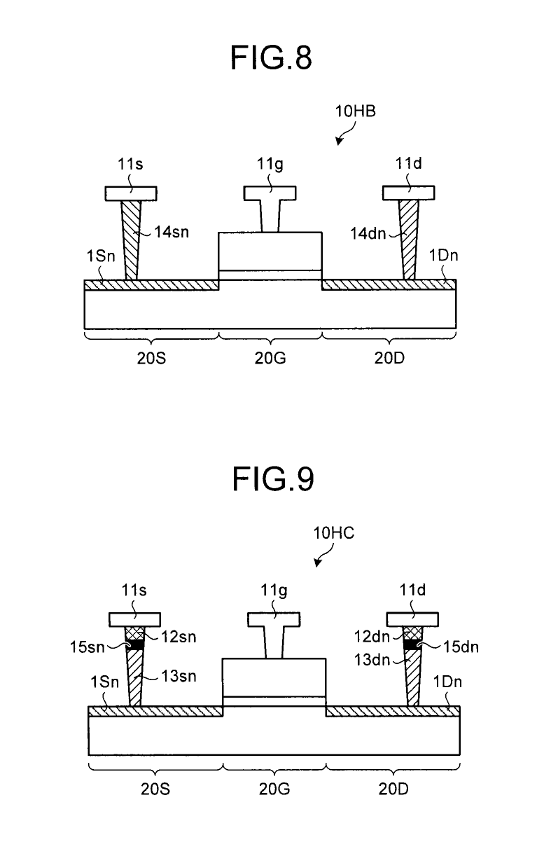

Next, a second embodiment will be described using FIG. 8. In the second embodiment, a concentration gradient is given to the plug portions 12dn and 13dn. Specifically, the polysilicon plug on the drain is formed such that the impurity concentration becomes lower as it goes from the wiring layer 11d toward the drain 20D.

FIG. 8 is a diagram illustrating an exemplary configuration of a transistor according to the second embodiment. Among the respective components of FIG. 8, the components achieving the same functions as those of the transistor 10HA of the first embodiment illustrated in FIG. 1 will be denoted with the same symbols, and the redundant description will not be repeated.

A transistor 10HB includes a plug portion 14dn instead of the plug portions 12dn and 13dn of the transistor 10HA. The upper portion side (the side near the wiring layer 11d) of the plug portion 14dn is formed to have an impurity concentration higher than that on the lower portion side (the side near the n-type diffusion layer 1Dn). Then, the plug portion 14dn is formed to have a lower impurity concentration as it goes from the upper portion side toward the lower portion side.

The plug portion 14dn, for example, is formed to have a higher carbon concentration as it goes from the upper portion side to the lower portion side. Therefore, in the plug portion 14dn, the concentration gradient is formed from the upper portion side toward the lower portion side. As a result, the plug portion 14dn comes into ohmic contact with the wiring layer 11d, and the resistance value of the plug portion 14dn becomes lower than a predetermined value.

In addition, the transistor 10HB includes a plug portion 14sninstead of the plug portions 12sn and 12sn of the transistor 10HA. The upper portion side (the side near the wiring layer 11s) of the plug portion 14sn is formed to have an impurity concentration higher than that on the lower portion side (the side near the n-type diffusion layer 1Sn). Then, the plug portion 14snis formed to have a lower impurity concentration as it goes from the upper portion side toward the lower portion side.

The plug portion 14sn, for example, is formed to have a higher carbon concentration as it goes from the upper portion side to the lower portion side. Therefore, in the plug portion 14sn, the concentration gradient is formed from the upper portion side toward the lower portion side. As a result, the plug portion 14sn comes into ohmic contact with the wiring layer 11s, and the resistance value of the plug portion 14sn becomes lower than a predetermined value.

Further, the CMOS transistor of this embodiment has the same configuration as that of the CMOS transistor of the first embodiment in the places other than the transistor 10HB.

In this way, in the second embodiment, the plug portion 14dn is formed to have a lower impurity concentration as it goes from the wiring layer 11d toward the drain 20D. With this configuration, in the drain 20D, the resistance in a portion between the high impurity layer and the gate 20G can be made large and the electric field of the pn junction between the diffusion layer and the substrate can be weakened. As a result, a high breakdown voltage transistor can be effectively formed while suppressing the increase of the circuit area.

### Third Embodiment

Next, a third embodiment will be described using FIG. 9. In the third embodiment, a concentration gradient is formed between the plug portions 12dn and 13dn. Therefore, the impurities of the plug portion 12dn are prevented from being diffused into the plug portion 13dn, and the impurities of the plug portion 13dn are prevented from being diffused into the plug portion 12dn.

FIG. 9 is a diagram illustrating an exemplary configuration of a transistor according to the third embodiment. Among the respective components of FIG. 9, the components achieving the same functions as those of the transistor 10HA of the first embodiment illustrated in FIG. 1 will be denoted with the same symbols, and the redundant description will not be repeated.

A transistor 10HC includes the plug portions 12dn, 13dn, and 15dn instead of the plug portions 12dn and 13dn of the transistor 10HA. The plug portion 15dn is disposed between the plug portions 12dn and 13dn.

Therefore, the plug portion 13dn is formed on the upper portion side of the n-type diffusion layer 1Dn, and the plug portion 15dn is formed on the upper portion side of the plug portion 13dn. Then, the plug portion 12dn is formed on the upper portion side of the plug portion 15dn. Therefore, the plug portion 12dn comes into ohmic contact with the wiring layer 11d, and the resistance values of the plug portions 13dn and 15dn become higher than a predetermined value.

In addition, the transistor 10HC includes the plug portions 12sn, 12sn, and 15sn instead of the plug portions 12sn and 12sn of the transistor 10HA. The plug portion 15sn is disposed between the plug portions 12sn and 12sn.

Therefore, the plug portion 12sn is formed on the upper layer side of the n-type diffusion layer 1Sn, and the plug portion 12sn is formed in the upper portion side of the plug portion 15sn. Then, the plug portion 12sn is formed on the upper portion side of the plug portion 15sn. Therefore, the plug portion 12sn comes into ohmic contact with the wiring layer 11s, and the resistance values of the plug portions 12sn and 15sn become higher than a predetermined value.

Further, the CMOS transistor of this embodiment has the same configuration as that of the CMOS transistor of the first embodiment in the places other than the transistor 10HC.

In this way, in the third embodiment, the plug portion 15dn formed of an oxide film is formed between the plug portions 12dn and 13dn. With this configuration, in the drain 20D, the resistance in a portion between the high impurity layer and the gate 20G can be made large and the electric field of the pn junction between the diffusion layer and the substrate can be weakened. As a result, a high breakdown voltage transistor can be effectively formed while suppressing the increase of the circuit area.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first transistor; and
a second transistor,
wherein the first transistor is connected to a first wiring through a wiring plug made of a material having a first resistance value smaller than a predetermined value, and
at least any one of a drain and a source of the second transistor is connected to a second wiring through a polysilicon plug made of a material having a second resistance value larger than the first resistance value.

2. The semiconductor device according to claim 1, wherein the polysilicon plug includes a first plug formed on a side near the second wiring and a second plug formed on a side near the second transistor, and the first plug has an impurity concentration at which the second wiring comes into ohmic contact, and the second plug has an impurity concentration lower than the first plug.

3. The semiconductor device according to claim 2, wherein the polysilicon plug includes a third plug which is formed by an oxide film between the first plug and the second plug.

4. The semiconductor device according to claim 1, wherein the polysilicon plug is formed to have a lower impurity concentration as it goes from the second wiring toward the second transistor.

5. The semiconductor device according to claim 4, wherein the polysilicon plug is formed to have a lower carbon concentration as it goes from the second wiring toward the second transistor.

6. The semiconductor device according to claim 1, wherein the wiring plug is made of metal.

7. The semiconductor device according to claim 1, wherein the wiring plug is made of polysilicon having an even impurity concentration.

8. The semiconductor device according to claim 1, wherein the polysilicon plug has an impurity concentration less than 1×10¹⁹/cm³ at a place connected to the second transistor.

9. The semiconductor device according to claim 1, wherein the polysilicon plug has an impurity concentration equal to or more than 1×10¹⁹/cm³ at a place connected to the second wiring.

10. The semiconductor device according to claim 2, wherein the second plug has an impurity concentration less than 1×10¹⁹/cm³.

11. The semiconductor device according to claim 2, wherein the first plug has an impurity concentration equal to or more than 1×10¹⁹/cm³.

12. The semiconductor device according to claim 1, wherein the drain or the source has an impurity concentration less than 1×10¹⁹/cm³.

13. The semiconductor device according to claim 1, wherein a gate oxide film of the second transistor is thicker than a gate oxide film of the first transistor.

14. A method of manufacturing a semiconductor device comprising:
forming a first transistor and a second transistor;
forming a polysilicon plug on an upper portion side of at least one of a drain and a source of the second transistor; and
forming a wiring plug on an upper portion side of the first transistor,
wherein the wiring plug is formed using a material having a first resistance value smaller than a predetermined value, and
the polysilicon plug is formed using a material having a second resistance value larger than the first resistance value.

15. The method of manufacturing the semiconductor device according to claim 14,
wherein the wiring plug is formed after the polysilicon plug is formed.

16. The method of manufacturing the semiconductor device according to claim 14,
wherein the polysilicon plug is connected to a wiring on an upper portion side, and includes a first plug formed on a side near the wiring and a second plug formed on a side near the second transistor, and
the first plug has an impurity concentration at which the wiring comes into ohmic contact, and the second plug has an impurity concentration lower than the first plug.

17. The method of manufacturing the semiconductor device according to claim 16,
wherein the polysilicon plug includes a third plug which is formed by an oxide film between the first plug and the second plug.

18. The method of manufacturing the semiconductor device according to claim 16,
wherein the polysilicon plug is formed to have a lower impurity concentration as it goes from the wiring toward the second transistor.

19. The method of manufacturing the semiconductor device according to claim 18, wherein the polysilicon plug is formed to have a lower carbon concentration as it goes from the wiring toward the second transistor.

20. The method of manufacturing the semiconductor device according to claim 14,
wherein the polysilicon plug has an impurity concentration less than 1×10¹⁹/cm³ at a place connected to the second transistor.
